(19) United States
(12) Patent Application Publication
(10) Pub. No.: US 2011/0214897 A1
(43) Pub. Date: Sep. 8, 2011

(54) Housing of waterproof electronic device

(75) Inventor: Toshihiro Yoshida, Mie (JP)

(73) Assignee: FUJI ELECTRIC SYSTEMS CO., LTD., Tokyo (JP)

(21) Appl. No.: 12/929,983

(22) Filed: Mar. 1, 2011

(30) Foreign Application Priority Data
Mar. 5, 2010 (JP) 2010-049210

(51) Int. Cl. H05K 5/06

(52) U.S. Cl. 174/50.51

(57) ABSTRACT

A housing for a waterproof electronic device includes a case with a front opening adapted to receive circuit components therein, and a front cover attached to the case so as to cover the case. The front cover is fitted onto a periphery of the front opening of the case so as to prevent rainwater from entering from outside. The case has an arched top plate, and includes, at a front of the case, a fitting stage, to which the front cover is fitted, so as to protrude from the case along the periphery of the front opening. The fitting stage has right and left side wall sections and at least one drain groove provided along peripheral surfaces of the top plate and both of the right and left side wall sections so that lower ends of the drain groove open downward at a bottom of the case.

### FIELD OF THE INVENTION

The present invention relates to a structure of a housing of an electronic device to waterproof specifications for which a device such as a general-purpose inverter device is taken as an object.

### BACKGROUND ART

When using an electronic device such as the above-described general-purpose inverter device in an environment such as outdoors, for preventing rainwater from entering the electronic device from the outside of the device, the housing of the device (an outer shell of die-cast aluminum or molded resin) is formed with a structure having a protecting function for drip-proof or rainproof.

In this case, in a related general-purpose inverter device, in a box-like case with an opened front in which circuit components are mounted, a front cover is fitted in watertight so as to prevent rainwater from entering from outside. As a means for providing the waterproof sealing, there is generally used a waterproof structure in which a sealing piece such as a waterproof packing or an O-ring packing is attached onto the periphery of the section and the case and the cover are fitted to each other (see JP-A-2008-154331, for example).

Incidentally, when a sealing piece such as a waterproof packing (rubber packing) is attached at a section where a case and a cover are fitted to each other as a means for providing the waterproof sealing of the housing as described above, for preventing the sealing piece from dropping, the sealing piece is bonded onto the opening of the case by manual work of using an adhesive. However, manual work of applying an adhesive and bonding a sealing piece is complicated and further requires some time for waiting hardening of the applied adhesive. In addition, variation in bonding performance occurs depending on skills of workers. Furthermore, there is also a problem in that while an electronic device is used for a long term, a packing piece is deteriorated to lower a waterproof function.

The invention has been made in view of the foregoing, and an object of the invention is to provide an improved waterproof structure for a housing of an electronic device so that rainwater from the outside is effectively prevented from entering the inside of a case with a system using no packing, which requires no sealing piece such as a packing and no complicated attaching work of bonding the sealing piece onto the opening of the case with an adhesive.

Further objects and advantages of the invention will be apparent from the following description of the invention.

### SUMMARY OF THE INVENTION

For achieving the above object, according to the invention, in a housing of a waterproof electronic device of an assembly of a box-like case with an opened front in which circuit components are mounted and a front cover is attached to the case so as to cover the case, with the front cover fitted onto the periphery of the front opening of the case so as to prevent rainwater from entering from the outside, the case has an arched top plate at the front of the case, and includes a fitting stage, to which the front cover is fitted, formed so as to protrude from the case along the periphery of the front opening of the case. The fitting stage has at least one drain groove provided along the peripheral surfaces of the top plate section and at both of the right and left side wall sections of the fitting stage so that the lower ends of the drain groove open downward at the bottom of the case (First aspect of the invention). The drain grooves can be specifically formed with embodiments as follows.

(1) In the housing formed as described above, in each of the right and left side walls on the front side of the case, the side wall is formed so that the lower part projects beyond the upper part to thereby make the fitting stage have the drain groove along the peripheral surface thereof with the lower part projecting ahead of the upper part to incline forward from the vertical direction (Second aspect of the invention).

(2) The fitting stage has two drain grooves provided along the outer peripheral surface thereof while being aligned in two rows as outer and inner ones (Third aspect of the invention).

With the housing structure as described in the foregoing, high waterproofness can be ensured without using any sealing piece such as a packing.

Namely, (1) with the case made to have an arched top plate, most of rainwater externally poring on the housing and its splashes flows rightward and leftward along the curved surface of the arched top plate to quickly flow down along the external surface of the sidewall of the case. Moreover, even in the case when a part of the rainwater and splashes penetrate into a gap between the fitted case and front cover, water penetrates into the gap before entering into the inside of the case, and flows down into the drain groove provided along the peripheral surface of the fitting stage to drop down along the drain groove onto the bottom side of the case to be then drained.

(2) In this case, the right and left side walls on the front side of the case are formed so that the lower part thereof projects ahead of the upper part to make the fitting stage have the drain groove with its lower part projecting ahead of the upper part to incline forward from the vertical direction. This makes the rainwater dropping into the drain groove flow downward along the side wall surface in the inclined drain groove without freely falling in the groove. Thus, free splashing of water drops into the inside of the case is inhibited to make it possible to effectively prevent water drops from entering the case.

(3) Furthermore, the fitting stage is made to have two drain grooves provided along the outer peripheral surface thereof while being aligned in two rows as outer and inner ones. This makes the drain groove arranged inside function as a backup drain groove for the outside drain groove. Thus, even in the case when an amount of rainwater, penetrating into the inside from the gap between the case and the cover, is so large that a part of the penetrating rainwater overflows the outside drain groove, the overflowed water can be made to flow down along the inside drain groove to be drained outward from the case, so that reliability of a waterproofing function is further increased.

In addition, with this waterproofing structure, the use of packing pieces and work requiring many hours for attaching packing pieces with the use of an adhesive like in the related housing are unnecessary to enable cost reduction. Furthermore, the problem of deterioration of a packing piece with age can be also solved. Moreover, the fitting stage having the drain grooves can be formed integrally with the case by means of a molding die of the case prepared for this purpose.

### BRIEF DESCRIPTION OF THE DRAWINGS

FIG. 1A is an exploded perspective view showing an example of the structure of a housing according to an embodiment of the invention;

FIG. 1B is an enlarged perspective view showing a portion 1B of a case shown in FIG. 1A;

FIG. 1C is an enlarged cross sectional side view of the portion 1B of the case shown in FIG. 1A showing a state with a front cover fitted to the case;

FIG. 2 is an external perspective view showing the upper half of the case shown in FIG. 1A viewed from the back side;

FIG. 3 is a side view showing the upper half of the case shown in FIG. 1A;

FIG. 4 is an external perspective view showing the housing shown in FIG. 1A in a state of being laid down sideways; and

FIG. 5 is an enlarged perspective view showing the corner section in the section 5 of the case shown in FIG. 4.

### DETAILED DESCRIPTION OF THE PREFERRED EMBODIMENT

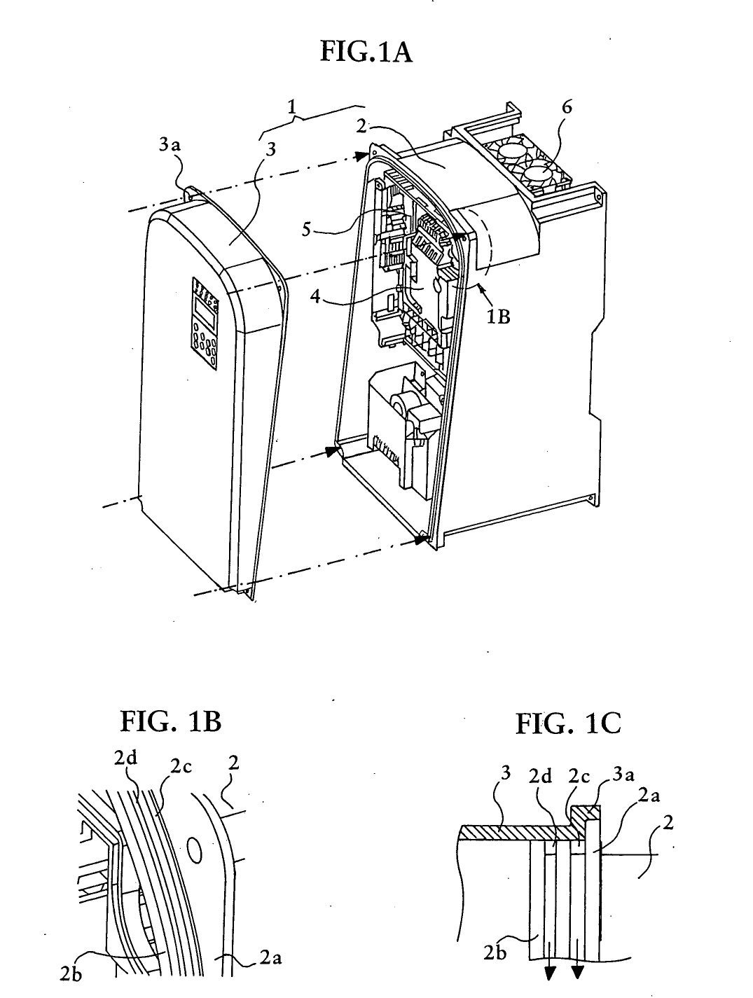

In the following, an embodiment according to the invention with a housing of a general-purpose inverter device taken as a subject will be explained on the basis of an example shown in FIG. 1A to FIG. 5.

FIG. 1A is an exploded perspective view showing an example of the structure of a housing according to an embodiment of the invention, FIG. 1B is an enlarged view of a portion 1B of a case shown in FIG. 1A and FIG. 1C is an enlarged cross sectional side view of the portion 1B of the case shown in FIG. 1A showing a state with a front cover fitted to the case;

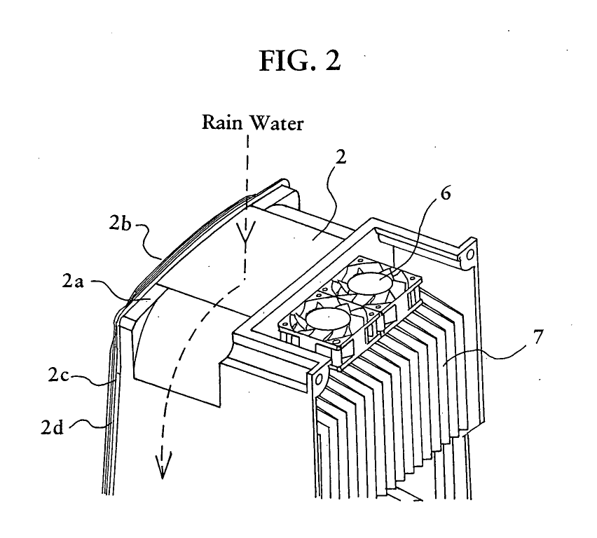

First, in FIG. 1A, reference numeral 1 denotes a housing (outer shell) of a general-purpose inverter device. The housing 1 is separately formed of a case 2 of an opened front type containing circuit parts of the inverter device and a front cover 3 fitted to the front opening of the case 2. Both of the case 2 and front cover 3 are made of die-cast aluminum or molded resin. Moreover, inside the case 2, there are mounted a power switching device (IGBT) 4 of an inverter device and a printed circuit board 5 of a control circuit. Furthermore, on the backside of the case 2, cooling fans 6 are placed so as to introduce cooling air to a heat sink 7 (see FIG. 2) for the power switching device 4.

Here, the case 2 has a top plate with an arch shape. Moreover, at each of the four corners of the front opening of the case 2, a flange 2a is provided on which each of peripheral flanges 3a, provided on the front cover 3 at positions corresponding to the positions of the flange 2a of the case 2, is placed so as to be secured to the flange 2a by means of a tightening screw.

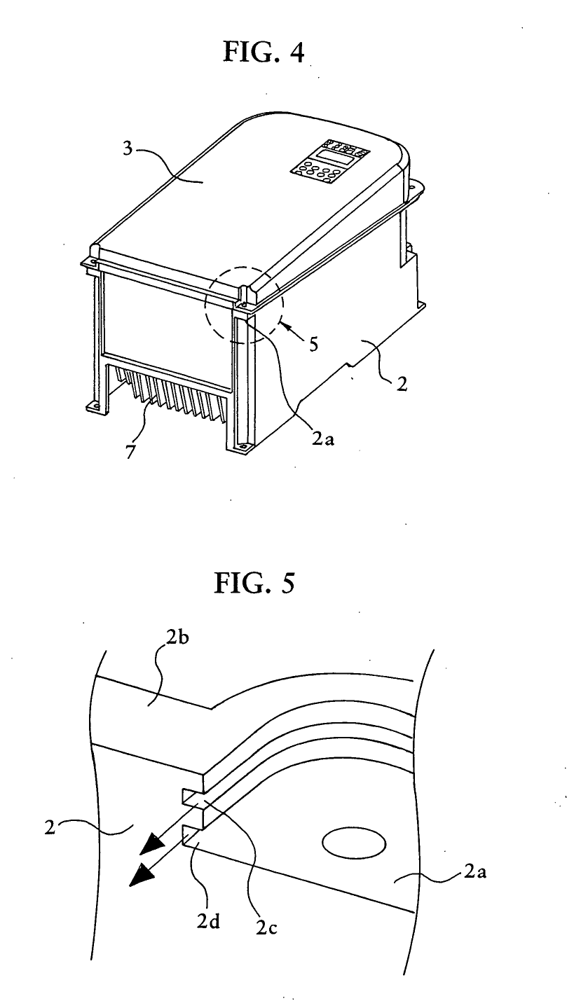

At the front of the case 2, a fitting stage 2b, to which the front cover 3 is fitted, is formed so as to protrude from the case 2 along the periphery of the front opening of the case 2. The fitting stage 2b has drain grooves 2c and 2d which are provided along the outer peripheral surface of the fitting stage 2b in the top plate section and both of the side wall sections of the case 2 while being aligned in two rows as outer and inner ones. The drain grooves 2c and 2d have their respective lower ends opened downward at the bottom of the case 2 as shown in FIG. 4 and FIG. 5.

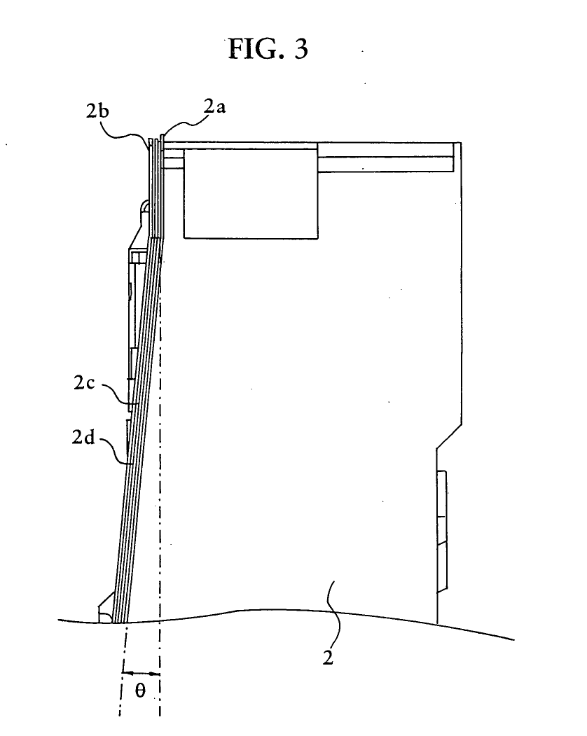

Furthermore, in each of the regions on the right and left side wall surfaces on the front side of the case 2, as shown in FIG. 3, the side wall is formed so that the lower part projects ahead of the upper part. This also makes the fitting stage 2b have the drain grooves 2c and 2d provided along the peripheral surface thereof with the lower part projecting ahead of the upper part to be slightly inclined forward from the vertical direction by an angle θ.

With the structure described above, in the assembled state of the housing 1 in which the front cover 3 is fitted to the front opening of the case 2 with the peripheral flanges 3a of the front cover 3 and the flanges 2a of the case 2 put together, the inner surface of the front cover 3 is fitted to the outer peripheral surface of the fitting stage 2b of the case 2 as shown in FIG. 1C.

This makes most of rainwater pouring on the housing 1 of an inverter device set outdoors flow rightward and leftward along the curved surface of the arched top plate as shown by an arrow of a broken line shown in FIG. 2. The rainwater then flows downward along the surface of the sidewall of the case 2 to be drained from the case 2. Moreover, even in the case when splashes of the rainwater penetrate into a small space between the fitted case 2 and front cover 3, the penetrating splashes flow down into the drain groove 2c provided along the peripheral surface of the fitting stage 2b to flow down in the drain groove 2c as shown by an arrow shown in FIG. 1C to be drained outward from the bottom end of the drain groove 2c. In addition, in the case when an amount of the penetrating rainwater is so large that a part of the penetrating rainwater overflows the drain groove 2c of a first row to penetrate into inside, the drain groove 2d of a second row functions as a back up drain groove to let overflowed water flow down in the drain groove 2d to be drained outward, so that highly reliable waterproof can be ensured.

Also in this case, as explained in the foregoing with reference to FIG. 3, the drain grooves 2c and 2d provided along the side wall surfaces of the fitting stage 2b are formed to be inclined forward, by which rainwater flowing down in the drain grooves 2c and 2d flows down along the side wall surfaces in the drain grooves 2c and 2d without freely scattering in the grooves. This inhibits unnecessary scattering of penetrated water to make it possible to more effectively prevent the penetrated water from entering inside the case 2.

In addition, the drain groove 2d on the outside operates to drain overflowed water from the drain groove 2c on the inside. However, an amount of the overflowed water is small. Therefore, the cross sectional area of the drain groove 2d is made smaller than the cross sectional area of the drain groove 2c. This does not make the width of the fitting stage 2b more than necessary.

While the present invention has been particularly shown and described with reference to the preferred embodiment thereof, it will be understood by those skilled in the art that the foregoing and other changes in form and details can be made therein without departing from the spirit and scope of the present invention.

The disclosure of Japanese patent application No. 2010-049210 filed on Mar. 5, 2010 is referred to and incorporated herein.

What is claimed is:

1. A housing for a waterproof electronic device, comprising:
a case with a front opening, adapted to receive circuit components therein, and
a front cover attached to the case so as to cover the case, the front cover being fitted onto a periphery of the front opening of the case so as to prevent rainwater from entering from outside,
wherein the case has an arched top plate, and includes, at a front of the case, a fitting stage, to which the front cover is fitted, so as to protrude from the case along the periphery of the front opening, the fitting stage having right and left side wall sections and at least one drain groove provided along peripheral surfaces of the top plate and both of the right and left side wall sections so that lower ends of the drain groove open downward at a bottom of the case.

2. The housing for a waterproof electronic device as claimed in claim 1, wherein in each of right and left side wall surfaces on a front side of the case, the side wall surface is formed so that a lower part projects ahead of an upper part to thereby make the fitting stage have the drain groove provided along the peripheral surface thereof with the lower part projecting ahead of the upper part to be inclined forward from a vertical direction.

3. The housing for a waterproof electronic device as claimed in claim 1, wherein the fitting stage has two drain grooves provided along an outer peripheral surface thereof while being aligned in two rows as outer and inner ones.

4. The housing for a waterproof electronic device as claimed in claim 2, wherein the front cover has an end face disposed over the fitting stage, the end face being inclined such that an upper part of the end face projects more than a lower part thereof reversely corresponding to the upper and lower parts of the side wall surface of the case.

5. The housing for a waterproof electronic device as claimed in claim 4, wherein the front cover has an outer surface extending substantially vertical, the end face being inclined relative to the outer surface.
